(19) United States
(12) Patent Application Publication
(10) Pub. No.: US 2014/0261689 A1
(43) Pub. Date: Sep. 18, 2014

(54) METHOD OF MANUFACTURING A PHOTOVOLTAIC DEVICE

(71) Applicant: First Solar, Inc., Perrysburg, OH (US)

(72) Inventors: Benyamin Buller, Sylvania, OH (US); Dan Damjanovic, Perrysburg, OH (US); Jing Guo, Sunnyvale, CA (US); David Hwang, Perrysburg, OH (US); Zhibo Zhao, Novi, MI (US)

(21) Appl. No.: 14/211,398

(22) Filed: Mar. 14, 2014

Related U.S. Application Data
(60) Provisional application No. 61/789,281, filed on Mar. 15, 2013.

(51) Int. Cl. H01L 31/0296; H01L 31/18

(52) U.S. Cl. CPC H01L 31/0296; H01L 31/1828
USPC 136/260; 438/85

(57) ABSTRACT

A photovoltaic device is disclosed, the device having a zinc-containing layer, such as a ZnO₁₋ₓSₓ layer, as a window layer, as part of a composite window layer, and/or as a buffer layer. Use of the ZnO₁₋ₓSₓ layer improves an overall efficiency of the photovoltaic device due to improved optical transmission thereof as compared to CdS window layers, and due to a improved quantum efficiency of the photovoltaic device in the blue light spectrum due to the presence of the ZnO₁₋ₓSₓ layer.

### CROSS-REFERENCE TO RELATED APPLICATION

This application claims the benefit of priority of U.S. Provisional Patent Application Ser. No. 61/789,281 filed on Mar. 15, 2013 hereby incorporated herein by reference in its entirety.

### FIELD OF THE INVENTION

The present disclosure relates to a photovoltaic device, and more particularly to a photovoltaic device having an improved efficiency and methods of forming the same.

### BACKGROUND OF THE INVENTION

Photovoltaic modules, devices, or cells, can include multiple layers (or coatings) created on a substrate (or superstrate). For example, a photovoltaic device can include a barrier layer, a transparent conductive oxide layer, a buffer layer, and a semiconductor layer formed in a stack on a substrate. Each layer may in turn include more than one layer or film. For example, a semiconductor window layer and a semiconductor absorber layer together can be considered a semiconductor layer. Additionally, each layer can cover all or a portion of the device and/or all or a portion of a layer or a substrate underlying the layer. For example, a “layer” can include any amount of any material that contacts all or a portion of a surface. Cadmium telluride has been used for the semiconductor layer because of its optimal band structure and a low cost of manufacturing.

The window layer is typically the top layer in a single-junction photovoltaic cell of a photovoltaic device formed from a high band gap material to allow transmittance of sunlight to underlying layers of the device. Annealing processes involving CdCl₂ known in the art may affect a thickness and/or performance of window layers formed from CdS. Thus, the annealing process must be tailored to minimize prolonged exposure of the CdS window layer to CdCl₂ and/or the elevated temperatures of the annealing process. Furthermore, a photovoltaic device having a window layer formed from a material with a band gap greater than that of CdS would result in a more efficient photovoltaic device. Accordingly, it would be desirable to develop a more efficient photovoltaic device.

### SUMMARY OF THE INVENTION

Concordant and congruous with the instant disclosure, a more efficient photovoltaic device has surprisingly been discovered.

In an embodiment of the invention, A photovoltaic device comprises a substrate; a zinc-containing layer disposed on the substrate; and a CdTe semiconductor layer disposed adjacent to the zinc-containing layer.

In another embodiment of the invention, a photovoltaic device comprises a substrate; a ZnO₁₋ₓSₓ layer disposed on the substrate; and a CdTe layer disposed adjacent to the ZnO₁₋ₓSₓ layer.

In another embodiment of the invention, a method of forming a photovoltaic device comprises the steps of applying a ZnO₁₋ₓSₓ layer on a substrate; and applying a semiconductor layer on the ZnO₁₋ₓSₓ layer, wherein the ZnO₁₋ₓSₓ layer is one of a window layer and a buffer layer.

### BRIEF DESCRIPTION OF THE DRAWINGS

The above, as well as other advantages of the present invention, will become readily apparent to those skilled in the art from the following detailed description of a preferred embodiment when considered in the light of the accompanying drawings in which:

FIG. 1 is a schematic, side view of a photovoltaic device having a zinc-containing layer disposed between a CdTe layer and a TCO layer according to another embodiment of the invention;

FIG. 2 is a schematic, side view of a photovoltaic device having a zinc-containing layer disposed between a CdS layer and a TCO layer according to an embodiment of the invention;

FIG. 3 is a schematic, side view of a photovoltaic device having a zinc-containing layer disposed between a CdTe layer and a CdS layer according to another embodiment of the invention;

FIG. 4 is a graph of quantum efficiency versus light wavelength for a ZnO₁₋ₓSₓ/CdTe bi-layer and a CdS/CdTe bi-layer; and

FIG. 5 is a graph of band gap versus composition of a ZnO₁₋ₓSₓ layer as a function of sulfur content.

### DETAILED DESCRIPTION OF THE INVENTION

The following description is merely exemplary in nature and is not intended to limit the present disclosure, application, or uses. It should also be understood that throughout the drawings, corresponding reference numerals indicate like or corresponding parts and features. In respect of the methods disclosed, the order of the steps presented is exemplary in nature, and thus, is not necessary or critical unless recited otherwise.

Referring now to the drawings, there is illustrated in FIG. 1 a photovoltaic device, indicated generally at 10. Furthermore as will be described herein, the photovoltaic device 10 includes one or more layers of material. Each layer can cover all or a portion of the device 10 and/or all or a portion of a layer or a substrate underlying the layer. For example, a “layer” can include any amount of any material that contacts all or a portion of a surface. FIG. 1 shows a side view of a portion of the photovoltaic device 10. The photovoltaic device 10 includes a transparent substrate 12. The transparent substrate 12 is formed of a material that provides rigid support, light transmission, chemical stability and typically includes one of a float glass, soda lime glass, polymer, or other suitable material. The photovoltaic device 10 includes a transparent conductive oxide (TCO) layer 14 formed on the substrate 12. The transparent conductive oxide layer 14 is formed of a material that provides low resistance electrical conduction, chemical and dimensional stability and typically includes one of a tin oxide, zinc oxide, cadmium stannate, combinations or doped variations thereof, or any other suitable material.

The photovoltaic device 10 of FIG. 1 includes a zinc-containing layer 16 as a window layer. As shown the zinc-container layer 16 is a ZnO₁₋ₓSₓ window layer 16 disposed between the TCO layer 14 and an absorber layer 18. The ZnO₁₋ₓSₓ window layer 16 may be grown in crystalline form of the Wurtzite type using RF sputter techniques, APCVD, LPCVD, MOCVD, through vaporization (close spaced vaporization, vapor transport deposition), pyrolysis, or atomic layer deposition (ALD), as explained in more detail below. As explained in more detail below, the band gap of the ZnO₁₋ₓSₓ window layer 16 may be tuned by affecting a ratio of sulfur to oxygen (S/O).

As shown in FIG. 1, the absorber layer 18 is formed of a photoactive material or combination of materials (as shown in FIG. 2 and explained in more detail below). The absorber layer 18 is formed from cadmium telluride. It is understood that other compounds and materials may be used, including silicon based semiconductors, copper indium gallium selenide, and other suitable materials. As shown, the absorber layer 18 has a thickness greater than a thickness of the ZnO₁₋ₓSₓ window layer 16. The photovoltaic device 10 includes a back contact layer 24. The back contact layer 24 is an electrically conductive material, typically selected from among silver, nickel, copper, aluminum, titanium, palladium, chromium, molybdenum, gold, and combinations thereof. In order to electrically connect the photovoltaic device to another device or system, the back contact layer includes polycrystalline zinc telluride (ZnTe). It is understood that the back contact layer 24 may be formed from a multi-layer stack including one or more of CdTe, CdZnTe, ZnTe, and ZnTe:Cu.

For purposes of simplicity in illustrating the invention, only the substrate 12, the TCO layer 14, the ZnO₁₋ₓSₓ window layer 16, the absorber layer 18, and the back contact layer 24 are shown. However, one of ordinary skill in the art should understand that one or more additional layers including, but not limited to, a barrier layer, additional buffer layers, a dielectric layer, and the like, formed from the same or different materials, may also be used in the photovoltaic device 10 of the present disclosure.

By using the ZnO₁₋ₓSₓ window layer 16 instead of a traditional window layer, such as CdS which has a lower quantum efficiency and absorbs at least some of the light in the blue light spectrum (around about 475 nm), a quantum efficiency of the photovoltaic device 10 in the blue light spectrum is improved. The ZnO₁₋ₓSₓ window layer 16 has improved optical transmission over that of CdS, thereby resulting in the improved photovoltaic device 10. A graph of quantum efficiency versus light wavelength is shown in FIG. 4. At about 475 nm, the quantum efficiency of the ZnO₁₋ₓSₓ window layer 16 is significantly higher than that of CdS, while the quantum efficiencies of the ZnO₁₋ₓSₓ window layer 16 and a CdS layer are approximately the same throughout the remainder of the light spectrum.

Furthermore, compared to a band gap of approximately 2.43 eV for CdS, the band gap of the ZnO₁₋ₓSₓ window layer 16 may be selectively varied between about 2.55 eV and about 3.60 eV by altering the stoichiometry of the ZnO₁₋ₓSₓ window layer 16, as best shown in FIG. 5. Positive results have been obtained for the ZnO₁₋ₓSₓ window layer 16 where x is between about 0.01 and about 1.0, between about 0.1 and about 0.9, and between about 0.2 and about 0.8.

By selectively varying and increasing the band gap of the ZnO₁₋ₓSₓ window layer 16 by altering the stoichiometry thereof, the optical response of the photovoltaic device 10 may be tuned and the conduction band offset optimized. Another limitation of using a CdS window layer is the lack of control over the rate flux of the material once a CdTe/CdS structure is exposed to CdCl₂ and annealed, as known in the art. A more aggressive CdCl₂ annealing step at elevated temperatures and repeated heat treatments has been shown to improve the quality of the CdTe semiconductor layer, but prolonged exposure to the CdCl₂ and prolonged exposure to elevated temperatures may lead to a minimized CdS window layer, thus affecting the performance of the photovoltaic device. However, due to a relatively higher melting point, the ZnO₁₋ₓSₓ window layer 16 provides a material more resistant to dissolution or interaction with adjacent layers of the photovoltaic device 10 during the CdCl₂ annealing process. Consequently, a more aggressive CdCl₂ annealing process may be used that prolongs the absorber layer 18 exposure to CdCl₂ and elevated temperatures may be used to result in an improved absorber layer 18 without adversely affecting the ZnO₁₋ₓSₓ window layer 16.

The band gap of the ZnO₁₋ₓSₓ window layer 16 may be selectively varied between about 2.55 eV and about 3.60 eV by manufacturing processes for controlling the stoichiometry thereof (see FIG. 5). For example, the sulfur content of the ZnO₁₋ₓSₓ window layer 16 may be controlled as a function of the deposition technique used to apply the ZnO₁₋ₓSₓ window layer 16. In one embodiment of the invention, the ZnO₁₋ₓSₓ window layer 16 may be grown in crystalline form of the Wurtzite variety on the photovoltaic device using one of the following: an RF sputtering process, a chemical vapor deposition from gas phases process (e.g., APCVD, LPCVD, MOCVD), through vaporization (e.g., close-spaced vaporization, VTD), pyrolysis process, or atomic layer deposition (ALD) process.

Using an RF sputtering process, the ZnO₁₋ₓSₓ window layer 16 is formed by using a ceramic ZnS target with Ar and O₂ as working and reactive gases, respectively. With the substrate 12 between about 300° C. and about 400° C. and an RF power at about 300 W, the ZnO₁₋ₓSₓ window layer 16 may have a thickness of between about 100 nm and about 700 nm. Using an ALD process, the TCO layer 14 is exposed to a zinc precursor (e.g., diethyl zinc) and subsequently converted to ZnO using a water pulse (or other oxygen containing fluid) and an H₂S pulse (or other sulfur containing fluid) for further inclusion of sulfur ions in the ZnO₁₋ₓSₓ window layer 16. By controlling the duration of the pulses, the stoichiometry of the ZnO₁₋ₓSₓ window layer 16 may be controlled. Due to the nature of the ALD process, typical growth of the ZnO₁₋ₓSₓ crystals may occur at relatively low temperatures from about 100° C. to about 200° C., thus minimizing costs associated with processing at higher temperatures.

Using an APCVD process, a temperature of the substrate 12 is typically higher than temperatures used for RF sputtering processes and ALD processes. For the APCVD process, an upper limit of the temperatures use during the APCVD process are around a softening temperature of the material forming the substrate 12 (e.g., soda lime glass). Thus, the tolerance of the ZnO₁₋ₓSₓ window layer 16 to excessive temperatures such as temperatures approaching the softening temperature of the substrate 12 facilitates the use of the APCVD process to result in a photovoltaic device 10 as described herein.

FIG. 2 illustrates a photovoltaic device 210 according to another embodiment of the invention. Furthermore as will be described herein, the photovoltaic device 210 includes one or more layers of material. Each layer can cover all or a portion of the device 210 and/or all or a portion of a layer or a substrate underlying the layer. For example, a “layer” can include any amount of any material that contacts all or a portion of a surface. FIG. 2 shows a side view of a portion of the photovoltaic device 210. The photovoltaic device 210 includes a transparent substrate 212. The transparent substrate 212 is formed of a material that provides rigid support, light transmission, chemical stability and typically includes one of a float glass, soda lime glass, polymer, or other suitable material. The photovoltaic device 210 includes a transparent conductive oxide (TCO) layer 214. The transparent conductive oxide layer 214 is formed of a material that provides low resistance electrical conduction, chemical and dimensional stability and typically includes one of a tin oxide, zinc oxide, cadmium stannate, combinations or doped variations thereof, or any other suitable material.

The photovoltaic device 210 of FIG. 2 includes a zinc-containing layer 216 as a buffer layer. As shown the zinc-containing layer 216 is a ZnO₁₋ₓSₓ buffer layer 216 disposed between the TCO layer 214 and an absorber layer 218. The ZnO₁₋ₓSₓ buffer layer 216 serves as a buffer layer to provide an interface between the TCO layer 216 and an n-type semiconductor layer 220 of the absorber layer 218, thereby resulting in sizable open-circuit voltage and efficiency enhancements of the photovoltaic device 210. The band gap of the ZnO₁₋ₓSₓ buffer layer 216 may be tuned by affecting a ratio of S/O. The ZnO₁₋ₓSₓ buffer layer 216 may be deposited using a number of deposition techniques, including ALD, APCVD, sputtering, and CBD. Sulfur content may be controlled as a function of deposition technique and deposition conditions, as explained in more detail below. The ZnO₁₋ₓSₓ buffer layer 216 may be grown in crystalline form of the Wurtzite type using RF sputter techniques, APCVD, LPCVD, MOCVD, through vaporization (close spaced vaporization, vapor transport deposition), pyrolysis, or atomic layer deposition (ALD).

As shown in FIG. 2, the absorber layer 218 is formed of a photoactive material or combination of materials. The absorber layer 218 includes one or more n-type semiconductor and/or one or more p-type semiconductors to form a p-n junction. In one embodiment, the absorber layer 218 is a semiconductor bi-layer including the n-type semiconductor 220, such as cadmium sulfide, for example, and a p-type semiconductor 222, such as cadmium telluride, for example. It is understood that other compounds and materials may be used, including silicon based semiconductors, copper indium gallium selenide, and other suitable materials. As shown, the p-type semiconductor 222 has a thickness greater than a thickness of the n-type semiconductor 220. The photovoltaic device 210 includes a back contact layer 224. The back contact layer 224 is an electrically conductive material, typically selected from among silver, nickel, copper, aluminum, titanium, palladium, chromium, molybdenum, gold, and combinations thereof. In order to electrically connect the photovoltaic device to another device or system, the back contact layer includes polycrystalline zinc telluride (ZnTe). It is understood that the back contact layer may be formed from a multi-layer stack including one or more of CdTe, CdZnTe, ZnTe, and ZnTe:Cu.

For purposes of simplicity in illustrating the invention, only the substrate 212, the TCO layer 214, the ZnO₁₋ₓSₓ buffer layer 216, the absorber layer 218, and the back contact layer 224 are shown. However, one of ordinary skill in the art should understand that one or more additional layers including, but not limited to, a barrier layer, additional buffer layers, a dielectric layer, and the like, formed from the same or different materials, may also be used in the photovoltaic device 210 of the present disclosure.

By using the ZnO₁₋ₓSₓ buffer layer 216, a quantum efficiency of the photovoltaic device 210 in the blue light spectrum may be improved. A graph of quantum efficiency versus light wavelength is shown in FIG. 4. At about 475 nm, the quantum efficiency of the ZnO₁₋ₓSₓ buffer layer 216 is significantly higher than that of CdS, while the quantum efficiencies of the ZnO₁₋ₓSₓ buffer layer 216 and a CdS layer are approximately the same throughout the remainder of the light spectrum. Furthermore, the ZnO₁₋ₓSₓ buffer layer 216 may have improved optical transmission qualities as compared to other buffer layers commonly used in the art, thereby resulting in the improved photovoltaic device 210.

The ZnO₁₋ₓSₓ buffer layer 216 also may provide a more resistive material to fluxing or interaction with adjacent layers of the photovoltaic device 210 during the CdCl₂ annealing process. Consequently, a more aggressive CdCl₂ annealing process may be used that prolongs the exposure of the absorber layer 218 to CdCl₂ and elevated temperatures may be used to result in an improved absorber layer 218 without adversely affecting the ZnO₁₋ₓSₓ buffer layer 216 and underlying n-type semiconductor layer 220 and/or p-type semiconductor layer 222.

In one embodiment of the invention, the ZnO₁₋ₓSₓ buffer layer 216 may be grown in crystalline form of the Wurtzite variety on the photovoltaic device using one of the following: an RF sputtering process, a chemical vapor deposition from gas phases process (e.g., APCVD, LPCVD, MOCVD), through vaporization (e.g., close-spaced vaporization, VTD), pyrolysis process, or atomic layer deposition (ALD) process.

Using an RF sputtering process, the ZnO₁₋ₓSₓ buffer layer 216 is formed by using a ceramic ZnS target with Ar and O₂ as working and reactive gases, respectively. With the substrate 212 between about 300° C. and about 400° C. and an RF power at about 300 W, the ZnO₁₋ₓSₓ buffer layer 216 may have a thickness of between about 100 nm and about 700 nm. Using an ALD process, the TCO layer 214 is exposed to a zinc precursor (e.g., diethyl zinc) and subsequently converted to ZnO using a water pulse (or other oxygen containing fluid) and an H₂S pulse (or other sulfur containing fluid) for further inclusion of sulfur ions in the ZnO₁₋ₓSₓ buffer layer 216. By controlling the duration of the pulses, the stoichiometry of the ZnO₁₋ₓSₓ buffer layer 216 may be controlled. Due to the nature of the ALD process, typical growth of the ZnO₁₋ₓSₓ crystals may occur at relatively low temperatures from about 100° C. to about 200° C., thus minimizing costs associated with processing at higher temperatures.

Using an APCVD process, a temperature of the substrate 212 is typically higher than temperatures used for RF sputtering processes and ALD processes. For the APCVD process, an upper limit of the temperatures use during the APCVD process are around a softening temperature of the material forming the substrate 212 (e.g., soda lime glass). Thus, the tolerance of the ZnO₁₋ₓSₓ buffer layer 216 to excessive temperatures such as temperatures approaching the softening temperature of the substrate 212 facilitates the use of the APCVD process to result in a photovoltaic device 210 as described herein.

FIG. 3 shows a photovoltaic device 310 according to another embodiment of the invention. The photovoltaic device 310 includes a transparent substrate 312. The transparent substrate 312 is formed of a material that provides rigid support, light transmission, chemical stability and typically includes one of a float glass, soda lime glass, polymer, or other suitable material. The photovoltaic device 310 includes a transparent conductive oxide (TCO) layer 314. The transparent conductive oxide layer 314 is formed of a material that provides low resistance electrical conduction, chemical and dimensional stability and typically includes one of a tin oxide, zinc oxide, cadmium stannate, combinations or doped variations thereof, or any other suitable material.

The photovoltaic device 310 of FIG. 3 includes a zinc-containing layer 316.

As shown, the zinc-containing layer is a ZnO₁₋ₓSₓ layer 316 disposed between an n-type semiconductor layer 320 and a p-type semiconductor layer 322. The ZnO₁₋ₓSₓ layer 316 forms a composite window layer with the n-type semiconductor layer 320. The band gap of the ZnO₁₋ₓSₓ layer 316 may be tuned by affecting a ratio of S/O. The ZnO₁₋ₓSₓ layer 316 may be deposited using a number of deposition techniques, including ALD, APCVD, sputtering, and CBD. Sulfur content may be controlled as a function of deposition technique and deposition conditions, as desired. The ZnO₁₋ₓSₓ layer 316 may be grown in crystalline form of the Wurtzite type using RF sputter techniques, APCVD, LPCVD, MOCVD, through vaporization (close spaced vaporization, vapor transport deposition), pyrolysis, or atomic layer deposition (ALD).

As shown in FIG. 3, the absorber layer 318 is formed of a photoactive material or combination of materials. Typically, the absorber layer 318 includes one or more n-type and/or one or more p-type semiconductors to form a p-n junction. In one embodiment, the absorber layer 318 is formed from a composite window layer of the n-type semiconductor 320, such as cadmium sulfide, for example, and the ZnO₁₋ₓSₓ layer 316 and a p-type semiconductor 322, such as cadmium telluride, for example. As shown, the p-type semiconductor 322 has a thickness greater than a thickness of the n-type semiconductor 320, and the n-type semiconductor 320 has a thickness greater than a thickness of the ZnO₁₋ₓSₓ layer 316. In one embodiment of the invention, the p-type semiconductor 322 has a thickness of about 10 to about 100 times thicker than the n-type semiconductor 320. The n-type semiconductor 320 has a thickness in the range of about 0.05 times and about 30 times the thickness of the ZnO₁₋ₓSₓ layer 316. It is understood that other compounds and materials may be used, including silicon based semiconductors, copper indium gallium selenide, and other suitable materials. As shown, the p-type semiconductor 322 has a thickness greater than a thickness of the n-type semiconductor 320. The photovoltaic device 310 includes a back contact layer 324. The back contact layer 324 is an electrically conductive material, typically selected from among silver, nickel, copper, aluminum, titanium, palladium, chromium, molybdenum, gold, and combinations thereof. In order to electrically connect the photovoltaic device to another device or system, the back contact layer includes polycrystalline zinc telluride (ZnTe). It is understood that the back contact layer may be formed from a multi-layer stack including one or more of CdTe, CdZnTe, ZnTe, and ZnTe:Cu.

For purposes of simplicity in illustrating the invention, only the substrate 312, the TCO layer 314, the ZnO₁₋ₓSₓ layer 316, the absorber layer 318, and the back contact layer 324 are shown, However, one of ordinary skill in the art should understand that one or more additional layers including, but not limited to, a barrier layer, additional buffer layers, a dielectric layer, and the like, formed from the same or different materials, may also be used in the photovoltaic device 310 of the present disclosure.

By using the ZnO₁₋ₓSₓ layer 316, a quantum efficiency of the photovoltaic device 310 in the blue light spectrum may be improved. A graph of quantum efficiency versus light wavelength is shown in FIG. 4. At about 475 nm, the quantum efficiency of the ZnO₁₋ₓSₓ layer 316 is significantly higher than that of CdS, while the quantum efficiencies of the ZnO₁₋ₓSₓ layer 316 and a CdS layer are approximately the same throughout the remainder of the light spectrum. Furthermore, the ZnO₁₋ₓSₓ layer 316 may have improved optical transmission qualities as compared to other buffer layers commonly used in the art, thereby resulting in the improved photovoltaic device 310.

The ZnO₁₋ₓSₓ layer 316 also may provide a more resistive material to fluxing or interaction with adjacent layers of the photovoltaic device 310 during the CdCl₂ annealing process. Consequently, a more aggressive CdCl₂ annealing process may be used that prolongs the exposure of the absorber layer 318 to CdCl₂ and elevated temperatures may be used to result in an improved absorber layer 318 without adversely affecting the ZnO₁₋ₓSₓ layer 316 and underlying n-type semiconductor layer 320 and/or p-type semiconductor layer 322.

In one embodiment of the invention, the ZnO₁₋ₓSₓ layer 316 may be grown in crystalline form of the Wurtzite variety on the photovoltaic device using one of the following: an RF sputtering process, a chemical vapor deposition from gas phases process (e.g., APCVD, LPCVD, MOCVD), through vaporization (e.g., close-spaced vaporization, VTD), pyrolysis process, or atomic layer deposition (ALD) process.

Using an RF sputtering process, the ZnO₁₋ₓSₓ layer 316 is formed by using a ceramic ZnS target with Ar and O₂ as working and reactive gases, respectively. With the substrate 312 between about 300° C. and about 400° C. and an RF power at about 300 W, the ZnO₁₋ₓSₓ layer 316 may have a thickness of between about 100 nm and about 700 nm. Using an ALD process, the TCO layer 314 is exposed to a zinc precursor (e.g., diethyl zinc) and subsequently converted to ZnO using a water pulse (or other oxygen containing fluid) and an H₂S pulse (or other sulfur containing fluid) for further inclusion of sulfur ions in the ZnO₁₋ₓSₓ layer 316. By controlling the duration of the pulses, the stoichiometry of the ZnO₁₋ₓSₓ layer 316 may be controlled. Due to the nature of the ALD process, typical growth of the ZnO₁₋ₓSₓ crystals may occur at relatively low temperatures from about 100° C. to about 200° C., thus minimizing costs associated with processing at higher temperatures.

Using an APCVD process, a temperature of the substrate 312 is typically higher than temperatures used for RF sputtering processes and ALD processes. For the APCVD process, an upper limit of the temperatures use during the APCVD process are around a softening temperature of the material forming the substrate 312 (e.g., soda lime glass). Thus, the tolerance of the ZnO₁₋ₓSₓ layer 316 to excessive temperatures such as temperatures approaching the softening temperature of the substrate 312 facilitates the use of the APCVD process to result in a photovoltaic device 310 as described herein.

While certain representative embodiments and details have been shown for purposes of illustrating the invention, it will be apparent to those skilled in the art that various changes may be made without departing from the scope of the disclosure, which is further described in the following appended claims.

What is claimed is:

1. A photovoltaic device comprising:
a substrate;
a zinc-containing layer disposed on the substrate; and
a CdTe semiconductor layer disposed adjacent to the zinc-containing layer.

2. The photovoltaic device of claim 1, wherein the zinc-containing layer is ZnO₁₋ₓSₓ .

3. The photovoltaic device of claim 2, wherein x is between about 0.01 and about 1.0.

4. The photovoltaic device of claim 3, wherein x is between about 0.1 and about 0.9.

5. The photovoltaic device of claim 4, wherein x is between about 0.2 and about 0.8.

6. The photovoltaic device of claim 1, wherein the zinc-containing layer is a window layer disposed between the substrate and the semiconductor layer.

7. The photovoltaic device of claim 1, wherein the semiconductor layer comprises a p-type semiconductor layer and an n-type semiconductor layer.

8. The photovoltaic device of claim 7, wherein the zinc-containing layer is disposed between the p-type semiconductor layer and the n-type semiconductor layer and forms a composite window layer with the n-type semiconductor layer.

9. The photovoltaic device of claim 8, wherein the zinc-containing layer has a thickness less than a thickness of the n-type semiconductor layer which has a thickness less than a thickness of the p-type semiconductor layer.

10. The photovoltaic device of. Claim 7, wherein the zinc-containing layer is a buffer layer disposed between the substrate and the n-type semiconductor layer.

11. The photovoltaic device of claim 1, further comprising a transparent conductive oxide layer disposed between the substrate and the zinc-containing layer.

12. A photovoltaic device comprising:
a substrate;
a ZnO₁₋ₓSₓ layer disposed on the substrate; and
a CdTe layer disposed adjacent to the ZnO₁₋ₓSₓ layer.

13. The photovoltaic device of claim 12, wherein x is between about 0.01 and about 1.0.

14. The photovoltaic device of claim 12, wherein the ZnO₁₋ₓSₓ layer is a window layer disposed between the substrate and the CdTe layer.

15. The photovoltaic device of claim 12, further comprising a CdS layer, wherein the ZnO₁₋ₓSₓ layer is disposed between the CdTe layer and the CdS layer and forms a composite window layer with the CdS layer.

16. A method of forming a photovoltaic device comprising the steps of:
applying a ZnO₁₋ₓSₓ layer on a substrate; and
applying a semiconductor layer on the ZnO₁₋ₓSₓ layer, wherein the ZnO₁₋ₓSₓ layer is one of a window layer and a buffer layer.

17. The method of claim 16, further comprising a step of selectively varying the stoichiometry of the ZnO₁₋ₓSₓ layer by controlling a content of the sulfur during the deposition process.

18. The method of claim 17, wherein the deposition process for applying the ZnO₁₋ₓSₓ layer is one of an RF sputtering process, a chemical vapor deposition process, and an atomic layer deposition process.

19. The method of claim 18, wherein the deposition process for applying the ZnO₁₋ₓSₓ layer is an RF sputtering process using a ZnS target with an Ar working gas and an 02 reactive gas.

20. The method of claim 18, wherein the deposition process for applying the ZnO₁₋ₓSₓ layer is an atomic layer deposition process whereby the substrate is exposed sequentially to a zinc precursor, an oxygen source for conversion of the zinc precursor to ZnO, a sulfur source for inclusion of a sulfur ion to the ZnO.
